(19) United States
(12) Patent Application Publication
(10) Pub. No.: US 2009/0020869 A1
(43) Pub. Date: Jan. 22, 2009

(54) INTERCONNECT JOINT

(76) Inventors: Qing Xue, Tempe, AZ (US); Shengquan E. Ou, Chandler, AZ (US); Sairam Agraharam, Phoenix, AZ (US)

Correspondence Address: INTEL CORPORATION;c/o INTELLEVATE, LLC, P.O. BOX 52050, MINNEAPOLIS, MN, 55402, US

(21) Appl. No.: 11/779,110

(22) Filed: Jul. 17, 2007

(51) Int. Cl. H01L 23/48

(52) U.S. Cl. 257/737; 257/E23.021

(57) ABSTRACT

An interconnect joint comprises a substrate (110), a solder resist layer (120) over the substrate, a solder resist opening (130) (having a top surface (131)) in the solder resist layer, a solder material (140) in the solder resist opening, and an electrically conducting structure (150) having a portion that extends into the solder material below the top of the solder resist opening.

### FIELD OF THE INVENTION

The disclosed embodiments of the invention relate generally to semiconductor dies, and relate more particularly to interconnect joints for use with semiconductor dies.

### BACKGROUND OF THE INVENTION

Controlled collapse chip connection (C4) is a technique used in the semiconductor industry for mounting a die or another semiconductor device onto a substrate. Solder bumps are the most widely-used C4 interconnect joint to attach the die to the substrate and to complete the I/O functions. Unfortunately, such solder bumps have several troublesome failure modes, among which are electromigration and bump cracking.

Electromigration is electron driven mass migration that occurs in solder that is exposed to high currents at elevated temperatures. Electromigration causes solder material to move from one pole to the other, resulting in mass loss that can generate voids and cracks in the solder material and possibly lead to complete solder bump failure. Bump cracking, which is especially problematic in larger dies/stiffer packages, occurs because of high thermomechanical stress induced by the substantial mismatch between the coefficient of thermal expansion (CTE) of the die and the substrate. High residual strain exists at the bumps near the corners of the die after die attachment reflow and cooling. The local shear stress may be higher than the solder shear strength, thus causing many (if not most) of the solder bumps at the corner regions to crack. If, as sometimes happens, the incoming substrate warpage produces an interconnect joint with very low stand-off height, a low volume bump, or some other problem, the bump cracking issue becomes even more pronounced.

Several attempts have been made to overcome the above and other problems in C4 interconnect joint technology. These attempts include the selection of optimized flux in order to form a better joint, and the flattening of the substrate in order to reduce substrate warpage. While they have some promise, these and the other existing solutions are flawed in that they do not address the root cause of the problems they attempt to solve. There continues to exist no truly effective and efficient solution for the failure modes of C4 solder interconnect joints. Accordingly, there exists a need for an interconnect joint that overcomes the electromigration and bump cracking problems.

### BRIEF DESCRIPTION OF THE DRAWINGS

The disclosed embodiments will be better understood from a reading of the following detailed description, taken in conjunction with:

FIG. 1, which is a cross-sectional view of an interconnect joint according to an embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, an interconnect joint comprises a substrate, a solder resist layer over the substrate, a solder resist opening (having a top) in the solder resist layer, an electrically conducting pad coated with a surface finish in the solder resist opening, a solder material in the solder resist opening over the electrically conducting pad, and an electrically conducting structure having a portion that extends into the solder material below the top of the solder resist opening.

Embodiments of the invention significantly improve the electromigration performance of a C4 solder joint. The relatively short distance between the tip of the electrically conducting structure and the bottom of solder resist opening significantly increases the resistance to mass transportation during electromigration and therefore greatly reduces the impact of electromigration on the interconnect joint. With the electrically conducting structure inserted into the solder resist opening, the solder material within the narrow gap between the electrically conducting structure and the substrate is strongly constrained by the solder resist opening and its surrounding contents. The electromigration improvement may be even more pronounced in embodiments where the chemical-metallurgical reaction converts all or significantly all of the solder into intermetallic compounds between the tip of the electrically conducting structure and the bottom of the solder resist opening.

Embodiments of the invention also completely change the mechanical conditions of the interconnect joint and create a robust joint between the die and the substrate. Certain embodiments may completely eliminate the bump cracking problem because the electrically conducting structure is much stronger than solder and also provides a higher standoff height which will substantially reduce residue strain. Because of its high strength, ductility, and electrical conductivity, the electrically conducting structure is able to withstand the shear stress created by the CTE mismatch between die and substrate without failure. A further advantage of embodiments of the invention is that such embodiments require that less flux be printed on the solder top right on the solder resist opening. The cleaner surroundings that result eliminate the need for a number of subsequent procedures, such as de-flux and pre-bake, that would otherwise be required, allowing a substantial reduction in cost and time.

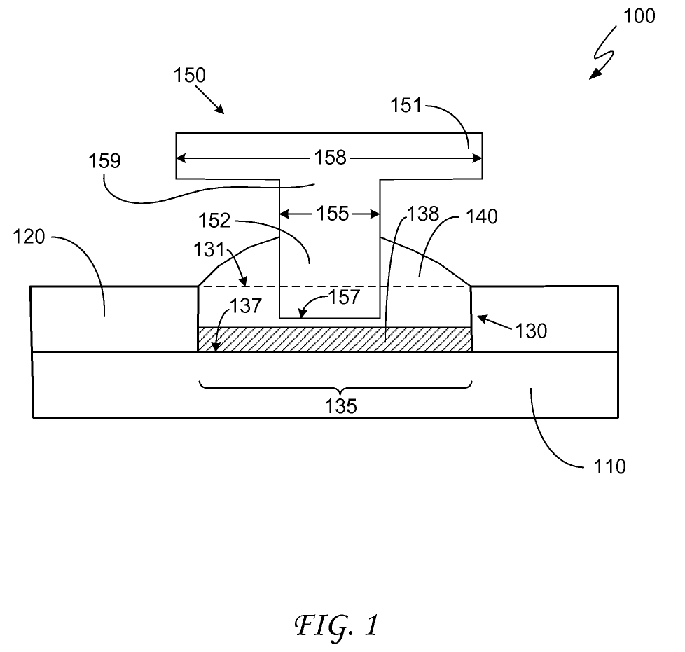

Referring now to the drawings, FIG. 1 is a cross-sectional view of an interconnect joint 100 according to an embodiment of the invention. As illustrated in FIG. 1, interconnect joint 100 comprises a substrate 110, a solder resist layer 120 over substrate 110, and a solder resist opening 130 in solder resist layer 120. Solder resist opening 130 has a top surface 131 and a floor 137. In one embodiment solder resist opening 130 further comprises a copper (or similar) pad 138 on floor 137. (It should be understood that, at least in certain embodiments, all of the copper pads (or other electrically conducting pads) referred to herein are coated with a surface finish according to techniques that are known in the art.) Interconnect joint 100 further comprises a solder material 140 (also referred to herein as “solder 140”) in solder resist opening 130 and an electrically conducting structure 150 having a portion (to be further described below) that extends into solder material 140 below top surface 131 of solder resist opening 130. In at least one embodiment, the portion of electrically conducting structure 150 extends far enough into solder resist opening 130 that it very nearly contacts copper pad 138.

In at least one embodiment, electrically conducting structure 150 is a copper bump. In one embodiment, solder material 140 is printed on solder resist opening 130 so as to extend from pad 138 up to top surface 131 or slightly higher. In one embodiment, electrically conducting structure 150 is arranged over copper pad 138 such that the tip of electrically conducting structure 150 is inserted into the solder resist opening and is held strongly by solder material 140.

Electrically conducting structure 150 comprises a base 151 and a post 152 extending from base 151. Base 151 may be wider, less wide, or equally as wide as solder resist opening 130. Post 152 has a tip 157 and an opposing end 159. Post 152, with its tip 157, is the portion (mentioned above) of electrically conducting structure 150 that extends into solder material 140. The length of post 152 varies according to the depth of solder resist opening 130 and to the required standoff height. In one embodiment, post 152 extends into solder resist opening 130 a distance that is greater than halfway between top surface 131 and copper pad 138 in solder resist opening 130. In a particular embodiment, post 152 extends into solder resist opening 130 such that tip 157 touches, or nearly touches, copper pad 138. The viscosity of solder material 140 at the reflow temperature may affect the final distance between copper pad 138 and tip 157; an additional force during processing may be necessary in order to press tip 157 as close as possible to copper pad 138.

As mentioned above, during electromigration in solder, a solder mass moves between electronic poles. Decreasing the distance between tip 157 (a first electronic pole) and copper pad 138 (a second electronic pole) will increase resistance (back stress) to electromigration. The wicking of solder 140 to the side walls of solder resist opening 130 won't carry high current density and acts as a buffer layer to prevent mechanical cracking at the intermetallic and solder interface. Embodiments of the invention therefore efficiently reduce the mass electromigration and extend the electromigration life beyond the service span.

The portion of solder 140 sandwiched between tip 157 and copper pad 138 is constrained by solder resist opening 130 leaving little room for mass transfer between the two electronic poles. In order for electromigration to occur in the illustrated geometry, the solder mass would have to be pushed to top surface 131 of solder resist opening 130—a relatively large distance from tip 157—because top surface 131 is the only place where solder 140 is free to move, being constrained everywhere else by the geometry. Solder mass transfer under these conditions requires much more energy than that needed under existing C4 bump designs.

More specifically, the electromigration mass flow is described by

$${J}_{em} = C \frac{D}{kT} ( {Z}^{*} e ρ j - Ω \frac{\partial σ}{\partial x} )$$

where C is the atom concentration per unit volume, D is the diffusion coefficient, k is the Boltzmann constant, T is the absolute temperature, Z* is the effective change number of electromigration, e is the electron charge, ρ is the resistivity, j is the current density, Ω is the atomic volume, and σ is the hydrostatic stress. Increasing dσ/dx will lead to a reduction of electromigration flow and therefore a decrease in the electromigration rate. Decreasing the distance separating tip 157 from copper pad 138 side will help to increase the stress gradient. It may also be advantageous to increase the stress level or confinement. Therefore, embodiments of the invention reduce the electromigration flow and improve the electromigration properties of C4 bumps.

Base 151 has a width 158 and post 152 has a width 155. As an example, width 158 may be approximately equal to width 155. As another example, width 158 may be as much as twice as large as width 155.

Solder resist opening 130 has a width 135. In embodiments where post 152 is cylindrical, width 155 is a diameter of post 152. Whether or not it is such a diameter, width 155 must be smaller than solder resist opening 130, i.e., smaller than width 135, so that post 152 can fit into solder resist opening 130. Particular dimensions depend on details of the specific solder resist opening, the copper bump diameter, and the minimum required shear strength of the copper bump. In one embodiment, width 155 is no greater than approximately 70 percent of width 135. In a particular embodiment, width 155 is between approximately 50 percent and approximately 70 percent of width 135. As an example, width 155 may be approximately 50 micrometers.

Electrically conducting structure 150 has strength and ductility sufficient to efficiently prevent shear failure along the bump horizontal direction (shear direction), unlike the solder material (e.g., tin-lead, tin-silver alloys, or tin-silver-copper alloys) of existing C4 bumps.

Solder resist layer 120 can support a much greater force than can a typical solder bump. Because most of solder material 140 is located within solder resist opening 130, solder material 140 is substantially constrained such that little deformation is allowed. Embodiments of the invention replace the existing load-bearing section of solder with a thin load-bearing section of copper or the like that has much higher shear strength and ductility than solder and that takes most of the shear deformation. Since the shear yield strength of copper is more than ten times that of the current solder materials, a copper bump with a diameter half that of a typical existing solder bump will still be 2-3 times stronger than that existing solder bump. Therefore, the embodiments will provide a robust interconnection without bump cracking. A typical solder bump height of an existing solder interconnect joint may be approximately 5 micrometers that holds the main shear deformation (the thick copper bump has much less deformation), while embodiments of interconnect joint 100 may have a thin copper bump height greater than ten times that amount. The copper bump height can be manipulated in order to reduce the strain while the “T’ shape of electrically conducting structure 150 generates a much lower stress (on base 151) experienced by interconnect joint 100. To reduce the local strain at the corners of tip 157, the height of solder resist opening 130 can be increased so that post 152 is inserted deeply into the solder resist opening 130. Thus the tip stress is significantly reduced, which further lowers the risk of the microcrack generation and the stress-assisted growth of electromigration defects, if any. As an example, under the same level of the CTE mismatch-induced displacement, the longer and thinner post 152 provides a large standoff height that may be ten times greater than that of existing solder bumps. The related shear strain will reduce up to one tenth although its shear modulus is approximately 3 to 4 times larger than that of the solder. A simple calculation using mechanical principles shows that if the diameter of post 152 is half of that of the existing bump, the corresponding shear force will drop to roughly one third of that in the existing bump. As a result, embodiments of the intention may significantly reduce the risk of many chip-side mechanical failures.

The following discussion relates to an estimation for reducing the risk of silicon-related failure on the die side of interconnect joint 100 according to an embodiment of the invention. Referring to an existing interconnect joint in which a copper bump sits on top of a solder bump and does not extend into the solder resist opening, and if we assume the CTE mismatch causes the same amount of displacement δ at the corner of the die, which is shared by both the copper bump and a portion of the solder bump between tip 157 and top surface 131 of solder resist opening 130, we have:

$$\begin{matrix}δ = {δ}_{1} + {δ}_{2} \\ = {γ}_{1} {H}_{1} + {γ}_{2} {H}_{2} \\ = \frac{{τ}_{1}}{{G}_{1}} {H}_{1} + \frac{{τ}_{2}}{{G}_{2}} {H}_{2} \\ = \frac{{F}_{1}}{{G}_{1} {A}_{1}} {H}_{1} + \frac{{F}_{2}}{{G}_{2} {A}_{2}} {H}_{2} \\ = \frac{F}{A} ( \frac{{H}_{1}}{{G}_{1}} + \frac{{H}_{2}}{{G}_{2}} ) ,\end{matrix} \qquad [ Eq . 1 ]$$

where δ is the displacement, γ is the shear strain, τ is the shear stress, F is the shear force, G is the shear modulus, H is the bump height, and A is the bump cross-sectional area. Subscripts 1 and 2 correspond respectively to a copper (Cu) bump and to a tin-lead (SnPb) (or tin-silver (SnAg)) solder bump. The bump height H₂ is referred to as the standoff height of the solder bump, i.e., the gap between tip 157 of post 152 and top surface 131 of solder resist opening 130. The area and total shear force are assumed to be identical in both copper and solder bumps, i.e., A₁=A₂=A, and F₁=F₂=F. For estimation purposes, G_{Cu} is taken to be approximately equal to 3-4 G_{SnPb}, and to be approximately equal to 1.5-2.5 G_{SnAg}. H₁ is taken to be approximately equal to 50 micrometers and H₂ is taken to be approximately equal to 5 micrometers.

Subscript 3 corresponds to the parameters for an interconnect joint according to an embodiment of the invention. Accordingly, H₃ is the bump height—the height between end 159 of post 152 and top surface 131 of solder resist opening 130 (ignoring the possible wicking)—for the copper bump according to an embodiment of the invention. Assuming that bump height is equal to the copper bump height in the existing interconnect joint as set forth in the preceding paragraph we have H₃=H₁+H₂. Note that H₃ is not the total height of the copper bump according to the embodiment of the invention but the height above top surface 131 of solder resist opening 130. We assume G₃=G₁=4G₂, and H₂=(0.1)H₁=solder standoff height. If we assume to obtain the same displacement then we have:

$$δ \begin{matrix}= {δ}_{3} \\ = {γ}_{3} {H}_{3} \\ = \frac{{τ}_{3}}{{G}_{3}} {H}_{3} \\ = \frac{{F}_{3}}{{A}_{3}} \frac{{H}_{3}}{{G}_{3}} .\end{matrix} \qquad [ Eq . 2 ]$$

Setting Eq. 1 equal to Eq. 2 yields:

$$\begin{matrix}\frac{{F}_{3}}{F} = \frac{{A}_{3} {G}_{3}}{{AH}_{3}} ( \frac{{H}_{1}}{{G}_{1}} + \frac{{H}_{2}}{{G}_{2}} ) \\ = \frac{{A}_{3}}{A} ( \frac{( {G}_{2} {H}_{1} + {G}_{1} {H}_{2} ) {G}_{3}}{( {H}_{1} + {H}_{2} ) {G}_{1} {G}_{2}} ) \\ = ( \frac{{H}_{1} + 4 {H}_{2}}{{H}_{1} + {H}_{2}} ) \frac{{A}_{3}}{A} \\ = 1.27 \frac{{d}_{3}^{2}}{{d}^{2}} \\ = {( 1.13 \frac{{d}_{3}}{d} )}^{2} ,\end{matrix} \qquad [ Eq . 3 ]$$

where d₃ is the diameter of the copper bump according to an embodiment of the invention and d is the diameter of an existing copper bump. Eq. 3 shows that if d₃=0.885 d, (a reduction of roughly 12% over the existing bump diameter), a copper bump according to an embodiment of the invention will experience the same shear force as does an existing copper bump. Reducing the diameter of the copper bump according to the embodiment of the invention even more than 12 percent compared to the existing copper bump yields a reduction in total shear force. In one embodiment of interconnect joint 100, the diameter of post 152 (i.e., width 155) is reduced at least 30 percent from the diameter of the existing copper bump, thus significantly reducing the shear force. If width 158 of base 151 maintains the same diameter as the existing copper bump, the embodiment of the invention greatly reduces the stress and lowers the risk of failure of chips.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the interconnect joint discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

1. An interconnect joint comprising:
a substrate;
a solder resist layer over the substrate;
a solder resist opening in the solder resist layer, the solder resist opening having a top;
a solder material in the solder resist opening; and
an electrically conducting structure having a portion that extends into the solder material below the top of the solder resist opening.

2. The interconnect joint of claim 1 wherein:
the electrically conducting structure comprises a copper bump.

3. The interconnect joint of claim 1 wherein:
the solder resist opening has a first dimension;
the copper bump has a second dimension; and
the second dimension is no greater than approximately 70 percent of the first dimension.

4. The interconnect joint of claim 3 wherein:
the second dimension is between approximately 50 percent and approximately 70 percent of the first dimension.

5. The interconnect joint of claim 1 wherein:
the electrically conducting structure comprises a base and a post extending from the base, the post having a tip; and
the post is the portion of the electrically conducting structure that extends into the solder material.

6. The interconnect joint of claim 5 wherein:
the solder resist opening further comprises a floor, and
the post extends into the solder resist opening a distance that is greater than halfway between the top of the solder resist opening and the floor of the solder resist opening.

7. The interconnect joint of claim 5 wherein:
the base has a third dimension and the post has a fourth dimension; and
the third dimension is greater than the fourth dimension.

8. The interconnect joint of claim 7 wherein:
the third dimension is at least twice as large as the fourth dimension.

9. An interconnect joint comprising:
a substrate;
a solder resist layer over the substrate;
a solder resist opening in the solder resist layer, the solder resist opening having a top and a floor,
a copper pad on the floor of the solder resist opening;
a solder material in the solder resist opening over the copper pad; and
a copper bump arranged over the copper pad such that a portion of the solder material in the solder resist opening is in a state that is approximately equal to hydrostatic equilibrium.

10. The interconnect joint of claim 9 wherein:
the copper bump has a portion that extends into the solder material below the top of the solder resist opening.

11. The interconnect joint of claim 10 wherein:
the solder resist opening has a first dimension;
the copper bump has a second dimension; and
the second dimension is between approximately 50 percent and approximately 70 percent of the first dimension.

12. The interconnect joint of claim 11 wherein:
the copper bump comprises a base and a post extending from the base, the post having a tip; and
the post is the portion of the copper bump that extends into the solder material.

13. The interconnect joint of claim 12 wherein:
the post extends into the solder resist opening a distance that is greater than halfway between the top of the solder resist opening and the floor of the solder resist opening.

14. The interconnect joint of claim 13 wherein:
the base has a third dimension and the post has a fourth dimension; and
the third dimension is at least twice as large as the fourth dimension.
